(19) United States
(12) Patent Application Publication
(10) Pub. No.: US 2023/0296325 A1
(43) Pub. Date: Sep. 21, 2023

(54) HEAT EXCHANGE SYSTEM

(71) Applicant: KENMEC MECHANICAL ENGINEERING CO., LTD., Taipei City (TW)

(72) Inventors: Ching-Fu HSIEH, Taipei City (TW); Shih-Chen CHANG, Taipei City (TW)

(73) Assignee: KENMEC MECHANICAL ENGINEERING CO., LTD., Taipei City (TW)

(21) Appl. No.: 17/824,920

(22) Filed: May 26, 2022

Related U.S. Application Data
(60) Provisional application No. 63/320,690, filed on Mar. 16, 2022.

(30) Foreign Application Priority Data
Apr. 13, 2022 (TW) 111114123

(51) Int. Cl. F28D 15/06; F28F 1/24

(52) U.S. Cl. CPC F28D 15/06; F28F 1/24; F28D 2021/0028

(57) ABSTRACT

The present disclosure provides a heat exchange system including a heat exchange module, a drive module, a buffer module, and a control module. The heat exchange module includes a first circulation pipe. A part of the first circulation pipe is penetrated into a cabinet. The driving module is connected to the heat exchange module and configured to drive a first fluid in the first circulation pipe to flow along the pipeline. The buffer module is in fluid communication with the first circulation pipe and includes a first control valve and a first storage space. The first control valve is between the first circulation pipe and the first storage space. The control module is electrically connected to the drive module and the buffer module. The control module includes a sensing device. The control module controls the first control valve and the drive module.

### CROSS REFERENCE TO RELATED DISCLOSURE

This application claims the priority benefit of U.S. Provisional Application No. 63/320,690, filed on Mar. 16, 2022, and TW Patent Application Number 111114123, filed on Apr. 13, 2022, the full disclosure of which is incorporated herein by reference.

### BACKGROUND

### Technical Field

The present disclosure is related to a heat exchange system, and in particular, a heat exchange system with cooling fluid therein that is effectively controlled.

### Related Art

In order to provide users with more convenient services, the number of central processing unit (CPU) disposed in the server is increasing, or at least the computing ability thereof is getting better and better. In addition, the number and/or performance of components such as a graphics processing unit (GPU), a hard disk, a power supply, a memory, etc. in the server is also increasing day by day. However, the increase in the number of components and/or the increase in performance also results in a large amount of waste heat. In order to allow the servers installed in the cabinets to be in a normal working environment, a water cooling system is generally used today to quickly remove the heat generated by the servers during operation. However, not all computer rooms are able to be connected to the chilling machine of the building. Further, even if the water cooling system can be connected to the chilling machine of the building, the cooling water may deteriorate too much due to the piping of the chilling machine may be not maintained, or the cooling water may be polluted due to the chilling machine may be connected to other equipment. Therefore, how to provide a heat dissipation system that can effectively help the servers in the cabinet to dissipate heat and can operate stably has become an urgent issue to be solved in the art.

### SUMMARY

The embodiments of the present disclosure disclose a heat exchange system, in order to solve the problem that the prior art cabinet is difficult to dissipate heat and can not operate stably.

In order to solve the above technical problems, the present disclosure is implemented as follows.

A heat exchange system is provided, which includes a heat exchange module, a drive module, a buffer module, and a control module. The heat exchange module includes a first circulation pipe, and a part of the first circulation pipe is penetrated into a cabinet to take away the heat of the cabinet. The driving module is connected to the heat exchange module and is configured to drive a first fluid in the first circulation pipe to flow along the first circulation pipe. The buffer module is in fluid communication with the first circulation pipe. The buffer module includes a first control valve and a first storage space, and the first control valve is located between the first circulation pipe and the first storage space. The control module is electrically connected to the driving module and the buffer module, and the control module includes a sensing device. The control module controls the first control valve to open or close according to a first sensing signal sent by the sensing device, and the control module controls the driving module according to the first sensing signal sent by the sensing device.

In some embodiments, the control module includes a calculate sub-module and a record sub-module. The calculate sub-module receives the first sensing signal from the sensing device, generates a control signal according to the first sensing signal, and sends the control signal to the buffer module and/or the drive module. The record sub-module receives the first sensing signal from the sensing device and stores a voltage information, a current information, a fluid pressure information, a fluid temperature information, and a fluid flow information of the first sensing signal.

In some embodiments, the heat exchange module further includes a cooling device, and the first circulation pipe is heat-exchanged with the cooling device.

In some embodiments, the cooling device includes a second circulation pipe and a chilling machine, and a part of the second circulation pipe is penetrated into the chilling machine to transfer the heat to the chilling machine. The first circulation pipe is heat-exchanged with but not in fluid communication with the second circulation pipe.

In some embodiments, the cooling device includes a plurality of heat dissipation fins, and the first circulation pipe is heat-exchanged with the plurality of heat dissipation fins.

In some embodiments, the cooling device includes a second circulation pipe, a compression heat exchange component, a plurality of heat dissipation fins, and a control component. The second circulation pipe is heat-exchanged with but not in fluid communication with the first circulation pipe. The compression heat exchange component is disposed in the second circulation pipe and compresses a second fluid in the second circulation pipe. The plurality of heat dissipation fins is heat-exchanged with the second circulation pipe. The control component is electrically connected to the compression heat exchange component. The control component includes a sensor, and the control component controls the compression heat exchange component according to a second sensing signal sent by the sensor.

In some embodiments, the cooling device further includes a buffer component. The buffer component is in fluid communication with the second circulation pipe. The buffer component includes a second control valve and a second storage space, and the second control valve is located between the second circulation pipe and storage space. The control component controls the second control valve to open or close according to the second sensing signal sent by the sensor.

In some embodiments, the compression heat exchange component is provided in plurality. At least one of the plural compression heat exchange components is in a running state, and at least one of the plural compression heat exchange components is in a closed state.

In some embodiments, the drive module includes a drive pump. The drive pump is disposed in the first circulation pipe and drives the first fluid in the first circulation pipe.

In some embodiments, the drive pump is provided in plurality. At least one of the plurality of drive pumps is in a running state, and at least one of the plurality of drive pumps is in a closed state.

In the present disclosure, the heat exchange system may monitor the first fluid in the first circulation pipe in real time by the sensing device of the control module, and the heat exchange system may determine whether the temperature and pressure of the first fluid meet the preset state according to the first sensing signal sent by the sensing device. When the pressure and/or temperature of the first fluid change, the control module may adjust the state of the first fluid through the driving module and even store excess first fluid through the storage module to maintain a stable thermal cycle. Therefore, through the above configuration, a heat exchange system that may effectively dissipate heat and may operate continuously and stably is realized by the present disclosure.

### BRIEF DESCRIPTION OF THE DRAWINGS

The figures described herein are used to provide a further understanding of the present disclosure and constitute a part of the present disclosure. The exemplary embodiments and descriptions of the present disclosure are used to illustrate the present disclosure and do not limit the present disclosure, in which:

FIG. 1 is a block diagram of the heat exchange system according to the first embodiment of the present disclosure.

FIG. 2 is a pipeline configuration schematic diagram of the heat exchange system according to the first embodiment of the present disclosure.

FIG. 3 is a schematic diagram of the heat exchange system according to the first embodiment of the present disclosure.

FIG. 4 is a block diagram of the heat exchange system according to the second embodiment of the present disclosure.

FIG. 5 is a schematic diagram of the heat exchange system according to the second embodiment of the present disclosure.

FIG. 6 is a block diagram of the heat exchange system according to the third embodiment of the present disclosure.

### DETAILED DESCRIPTION OF THE EMBODIMENTS

In order to make the objectives, technical solutions, and advantages of the present disclosure clearer, the technical solutions of the present disclosure will be described clearly and completely in conjunction with specific embodiments and the figures of the present disclosure. Obviously, the described embodiments are only a part of the embodiments of the present disclosure, rather than all the embodiments. Based on the embodiments in the present disclosure, all other embodiments obtained by a person of ordinary skill in the art without creative work fall within the protection scope of this disclosure.

The following description is of the best-contemplated mode of carrying out the present disclosure. This description is made for the purpose of illustrating the general principles of the present disclosure and should not be taken in a limiting sense. The scope of the present disclosure is best determined by reference to the appended claims.

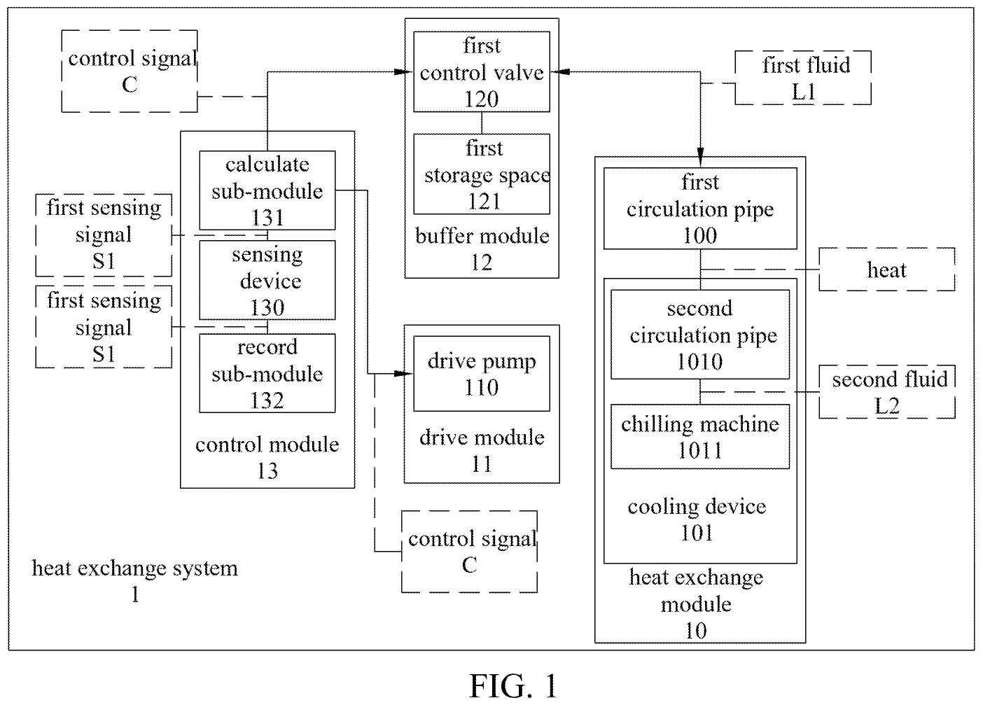

FIG. 1 is a block diagram of the heat exchange system according to the first embodiment of the present disclosure. As shown in the figure, the heat exchange system 1 includes a heat exchange module 10, a drive module 11, a buffer module 12, and a control module 13.

The heat exchange module 10 includes a first circulation pipe 100, and a part of the first circulation pipe 100 is penetrated into a cabinet to take away heat of the cabinet. Wherein, a first fluid L1 is stored in the first circulation pipe 100. In the present disclosure, the term “cabinet” refers to a carrier device with servers disposed wherein. For example, the cabinet may be a server carrying device located in a computer room, and the server may include but is not limited to components such as a central processing unit, a graphics processing unit, a hard disk, a power supply, and a memory. However, the present disclosure is not limited to the location of the cabinet. By making a part of the first circulation pipe 100 penetrated into the cabinet, the first fluid L1 flowing along the first circulation pipe 100 may effectively remove the heat of the cabinet, so that the cabinet may maintain a stable working temperature. It should be noted that the “penetrate” means that a part of the first circulation pipe 100 is located in the cabinet, and the first circulation pipe 100 located in the cabinet may also be connected or serially connected with large-area heat dissipation blocks, heat dissipation plates, and heat dissipation fins, etc. to increase the rate of heat exchange.

In some embodiments, the first fluid L1 may be water, aqueous glycol solution, or compatible cooling fluid. Preferably, the first fluid L1 may be deionized water. More preferably, the first fluid L1 is deionized water added with anti-corrosion inhibitors and bactericides, which may avoid reducing the heat dissipation capacity and reliability due to corrosion, scaling, and microbial growth of the pipeline. Still more preferably, the first fluid L1 is deionized water that may satisfy the following conditions:

| | | |
|---|---|---|
| Conductivity <1 uS/cm | Aluminum <0.05 mg/L | Potassium <0.01 mg/L |
| pH 6-8 | Antimony <0.1 mg/L | Magnesium <0.01 mg/L |
| Evaporation residue <10 mg/L | Arsenic <0.1 mg/L | Manganese <0.01 mg/L |
| Turbidity <=1.0 NTU | Boron <0.05 mg/L | Molybdenum <0.01 mg/L |
| Chloride such as chlorine <1.0 mg/L | Barium <0.01 mg/L | Sodium <0.02 mg/L |
| Sulfates such as calcium | Calcium <0.01 mg/L | Nickel <0.01 mg/L |
| carbonate <0.5 mg/L | | |
| Heavy metal (Lead) <0.1 ppm | Cadmium <0.01 mg/L | Tin <0.1 mg/L |
| Silica <0.01 ppm | Chromium <0.01 mg/L | Zinc <0.01 mg/L |
| Nitrate <0.5 mg/L | Copper <0.01 mg/L | |
| Nitrite <0.5 mg/L | Iron <0.01 mg/L | |

In some embodiments, the temperature range of the first fluid L1 is within 10° C. to 45° C., which needs to be above the environment dew point.

The drive module 11 is connected to the heat exchange module 10 and configured to drive the first fluid L1 in the first circulation pipe 100 to flow along the pipeline. In some embodiments, the drive module 11 includes a drive pump 110. The drive pump 110 is disposed in the first circulation pipe 100 and drives the first fluid L1 in the first circulation pipe 100. For example, the drive pump 110 may be a plunger pump of a pressure test pump, which uses a relief valve to control pressure and a throttle valve to control flow. However, the present disclosure is not limited thereto. Any pumps well known to a person having ordinary skills in the art may be applied to the present disclosure. For example, the drive pump 110 may also be a metering pump or other suitable pumps.

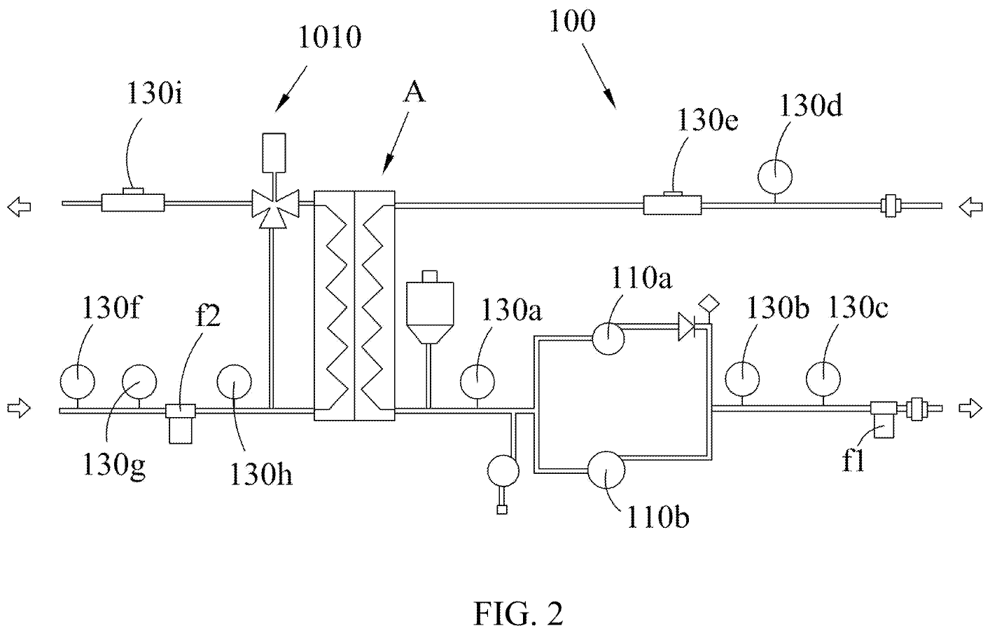

In some embodiments, the drive pump 110 is provided in plurality. At least one of the plurality of drive pumps 110 is in a running state, and at least one of the plurality of drive pumps 110 is in a closed state. FIG. 2 is a schematic diagram of the pipeline configuration of the heat exchange system according to the first embodiment of the present disclosure, and the right half of FIG. 2 is a partial schematic diagram of the first circulation pipe 100. Take the present embodiment as an example, the number of drive pump 110 may be two, and the two drive pumps 110 (ie, the first drive pump 110a and the second drive pump 110b) are respectively connected in series in the first circulation pipe 100. When one of the two drive pumps 110 is in a running state, the other of the two drive pumps 110 is in a closed state. In this way, the entire drive module 11 only relies on one drive pump 110 to drive the delivery of the first fluid L1, while the other drive pump 110 is used for backup. In this case, the two drive pumps 110 may be turned off alternately at a fixed cycle to increase the service life of the equipment. In addition, through the design of alternate activation, the drive module 11 may not affect the operation of the heat exchange system 1 during maintenance. It should be noted that the number mentioned above is only an example. In other embodiments, the number of drive pump 110 may also be three, four, or more than four, and at least one of the drive pumps 110 is in a closed state.

The buffer module 12 is in fluid communication with the first circulation pipe 100, and the buffer module 12 includes a first control valve 120 and first storage space 121. The first control valve 120 is located between the first circulation pipe 100 and the first storage space 121. In the present disclosure, the first storage space 121 may be a storage device such as a hollow liquid storage tank, a liquid storage bucket, etc., which is used for storing or replenishing the first fluid L1.

For example, when the environment temperature rises and the volume of the first fluid L1 increases, the first control valve 120 may be set to open so that the first fluid L1 flows into the first storage space 121 from the first circulation pipe 100. In this way, the parameters such as flow rate and pressure of the first fluid L1 in the first circulation pipe 100 may be adjusted according to preset or real time settings. Conversely, when the volume of the first fluid L1 decreases due to a sudden drop in the environment temperature, or when the flow and pressure of the first fluid L1 need to be increased to improve the heat dissipation performance, the first control valve 120 may also be set to open so that part of the first fluid L1 flows into the first circulation pipe 100 from the first storage space 121.

The control module 13 is electrically connected to the drive module 11 and the buffer module 12, and the control module 13 includes a sensing device 130. The control module 13 controls the first control valve 120 to open or close according to a first sensing signal S1 sent by the sensing device 130, and the control module 13 controls the drive module 11 according to the first sensing signal S1 sent by the sensing device 130. In some embodiments, the sensing device 130 may include one or more of a voltage sensor, a current sensor, a fluid temperature sensor, a fluid pressure sensor, a fluid flow meter, and/or various types of sensors well known to a person having ordinary skills in the art to effectively monitor the status of the heat exchange module 10. Specifically, the fluid temperature sensor, the fluid pressure sensor, the fluid flow meter, and other suitable sensors generate the first sensing signal S1 according to the measured state of the first fluid L1. The first sensing signal S1 may include a voltage information, a current information, and a fluid pressure information, a fluid temperature information, and a fluid flow information, but the present disclosure is not limited thereto.

Take the schematic diagram of FIG. 2 as an example, wherein the right half of the diagram represents the first circulation pipe 100. The first circulation pipe 100 may be provided/connected with the sensing devices 130 such as a fluid pressure sensor 130a, a fluid pressure sensor 130b, a fluid temperature sensor 130c, a fluid temperature sensor 130d, and a fluid flow meter 130e, and the drive pumps 110 such as the first drive pump 110a and the second drive pump 110b.

Wherein, the fluid pressure sensor 130a is used to sense the pressure of the first fluid L1 before being pressurized through the first drive pump 110a and/or the second drive pump 110b, and the fluid pressure sensor 130b is used to sense the pressure of the first fluid L1 after being pressurized through the first drive pump 110a and/or the second drive pump 110b. The fluid temperature sensor 130c is used to sense the temperature of the first fluid L1 after absorbing the heat of the cabinet 2 (ie, in the water return state), and the fluid temperature sensor 130d is used to sense the temperature of the first fluid L1 before absorbing the heat of the cabinet 2 (ie, in the water outlet state). The fluid flow meter 130e is used to sense the flow rate of the first fluid L1 in the first circulation pipe 100.

Through the configuration mentioned above, the control module 13 may accurately confirm the state of the first fluid L1 in the first circulation pipe 100, so as to control the drive module 11 and/or the buffer module 12 in real time. When one or more of the temperature, pressure, and flow rate of the first fluid L1 is abnormal, the control module 13 sends a control signal C according to the first sensing signal S1 sent by the sensing devices 130 to control the drive module 11 to stop running, or control the first control valve 120 to open/close to adjust the total amount of the first fluid L1 in the first circulation pipe 100.

It should be noted that the configuration mentioned above is only an example of the present disclosure, and the present disclosure is not limited thereto. In other embodiments, the first circulation pipe 100 may also be provided with/connected with other sensors of different types and numbers, so as to monitor the state of the heat exchange module 10 more effectively.

As shown in FIG. 1, in some embodiments, the control module 13 includes a calculate sub-module 131 and a record sub-module 132. The calculate sub-module 131 receives the first sensing signal S1 from the sensing device 130, generates the control signal C according to the first sensing signal S1, and sends the control signal C to the buffer module 12 and/or the drive module 11. For example, the calculate sub-module 131 may include a suitable processor such as a central processing unit, a microprocessor, etc., which determines the state of the first fluid L1 according to a voltage information, a current information, a fluid pressure information, a fluid temperature information, and a fluid flow information of the first sensing signal S1, and generates the control signal C corresponding to the first sensing signal S1 to the drive module 11 and/or the buffer module 12 to adjust the state of the first fluid L1 in the first circulation pipe 100.

The record sub-module 132 receives the first sensing signal S1 from the sensing device 130, and stores the voltage information, the current information, the fluid pressure information, the fluid temperature information, and the fluid flow information of the first sensing signal S1. In the present disclosure, the record sub-module 132 may include a conventional hard disk drive (HDD), a solid state drive (SDD), a random access memory (RAM), an optical storage device (CD, DVD), or other suitable storage devices, to record the information mentioned above of the first sensing signal S1.

In some embodiments, the record sub-module 132 may also store a preset voltage information, a preset current information, a preset fluid pressure information, a preset fluid temperature information, and a preset fluid flow information. When the calculate sub-module 131 determines that the voltage information, the current information, the fluid pressure information, the fluid temperature information, and the fluid flow information detected in real time are different from the parameters mentioned above, the calculate sub-module 131 may adjust the drive module 11 and/or the buffer module 12 according to the situation, and/or issue an alarm to maintenance personnel.

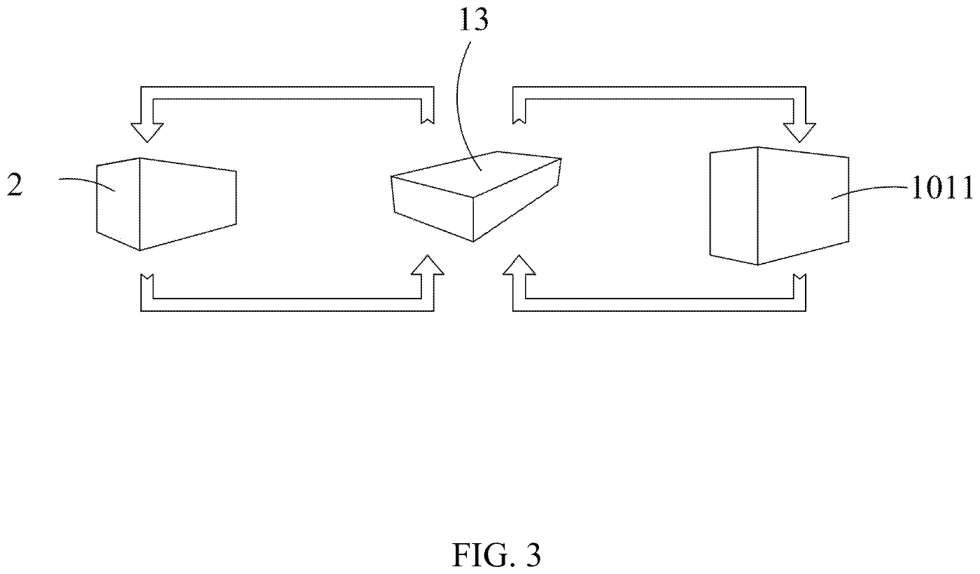

As shown in FIG. 1 and FIG. 3, wherein FIG. 3 is a schematic diagram of the heat exchange system of the first embodiment of the present disclosure. In the present embodiment, the heat exchange module 10 is used to absorb the heat of the cabinet 2. The heat exchange module 10 further includes a cooling device 101, and the first circulation pipe 100 is heat-exchanged with the cooling device 101. More specifically, the cooling device 101 includes a second circulation pipe 1010 and a chilling machine 1011. A part of the second circulation pipe 1010 is penetrated into the chilling machine 1011 to transfer the heat to the chilling machine 1011. The first circulation pipe 100 is heat-exchanged with but not in fluid communication with the second circulation pipe 1010. The second fluid L2 is stored in the second circulation pipe 1010. In the present embodiment, the chilling machine 1011 may be a large chilling machine 1011 of a commercial or industrial building type, which is disposed outside the building and conducts heat-exchanged through a cooling water tower. However, the present disclosure is not limited thereto, the chilling machine 1011 may also be a dedicated cooler or a dedicated cooling tower, which may also be disposed in a building.

By letting the first fluid L1 and the second fluid L2 respectively circulate in the first circulation pipe 100 and the second circulation pipe 1010, and letting the first fluid L1 and the second fluid L2 be close to each other (area A in FIG. 2) to conduct heat-exchanged, the present embodiment effectively conducts the heat of the cabinet 2 from the first fluid L1 and the second fluid L2 to the outside (for example, outside the building) in sequence. It should be noted that the first fluid L1 and the second fluid L2 of the present disclosure only use heat conduction and heat radiation for heat-exchanging, and at most indirect heat convection (for example, the air that may flow in the area A) for heat-exchanging. Which will not actually be in fluid communication with each other, so as to effectively prevent impurities and dirt from contaminating the first circulation pipe 100.

In some embodiments, the heat dissipation system of the present disclosure may be divided into a primary fluid circuit and a secondary fluid circuit. Take the right half of FIG. 3 as an example, components such as the control module 13, the second circulation pipe 1010, and the chilling machine 1011 are defined as the units of the primary fluid circuit. Take the left half of FIG. 3 as an example, components such as the control module 13, the first circulation pipe 100, and the cabinet 2 are defined as the units of the secondary fluid circuit. That is, the present embodiment may be regarded as being composed of the fluid circuits on the left and right sides. Accordingly, the term “second” in the present disclosure in relation to the primary fluid circuit may also be referred to as “primary fluid circuit”. For example, elements such as “second” circulation pipe 1010, “second” fluid L2, and “second” filter f2 may be referred to as “primary fluid circuit” circulation pipe, “primary fluid circuit” fluid, and “primary fluid circuit” filter device.

Similarly, the term “first” in the present disclosure in relation to the secondary fluid circuit may also be referred to as the “secondary fluid circuit”. For example, elements such as “first” circulation pipe 100, “first” fluid L1, “first” control valve 120, “first” storage space 121, “first” sensing signal S1, and “first” filter f1 may be referred to as “secondary fluid circuit” circulation pipe, “secondary fluid circuit” fluid, “secondary fluid circuit” control valve, “secondary fluid circuit” storage space, and “secondary fluid circuit” filter.

Obviously, the terms “first”, “second”, “primary fluid circuit”, and “secondary fluid circuit” used in the present disclosure are only used to distinguish different elements or components, which cannot be construed as indicating or implying relative importance or its sequential relationship.

In some embodiments, the second fluid L2 may include water or an aqueous glycol solution, but the present is not limited thereto. Preferably, the second fluid L2 may also contain deionized water. More preferably, the second fluid L2 is deionized water added with anti-corrosion inhibitors and bactericides. Still more preferably, the second fluid L2 may be the same as the first fluid L1 satisfying the conditions in the above table.

Take the schematic diagram of FIG. 2 as an example, wherein the left half of the diagram represents the second circulation pipe 1010. The second circulation pipe 1010 also may be provided/connected with sensing devices 130 such as a fluid pressure sensor 130g, a fluid pressure sensor 130h, a fluid temperature sensor 130f, and a fluid flowmeter 130i. The fluid pressure sensor 130g is used to sense the pressure of the second fluid L2. The fluid pressure sensor 130h is used to sense the pressure of the second fluid L2. The fluid temperature sensor 130f is used to sense the temperature of the second fluid L2 after absorbing the heat of the first fluid L1 (ie, backwater state). The fluid flow meter 130i is used to sense the flow rate of the second fluid L2 in the second circulation pipe 1010.

In some embodiments, the heat exchange system 1 may also include a filter, and the filter may be disposed on the first circulation pipe 100 and/or the second circulation pipe 1010 to effectively filter impurities in the pipeline. For example, the first circulation pipe 100 and the second circulation pipe 1010 may be respectively provided with a first filter f1 and a second filter f2, which are located at the positions shown in FIG. 2. However, the present disclosure is not limited thereto. Filters with different filtering levels may be disposed by a person having ordinary skills in the art according to requirements, and these filters may be disposed at positions different from those shown in FIG. 2.

As mentioned above, the heat exchange system 1 in the present embodiment adopts the connection mode of FIG. 3, which monitors the entire heat exchange process by the control module 13 located between the cooling device 101 and the cabinet 2, thereby effectively and stably enabling the cabinet 2 to be in a preset working environment. It should be noted that although FIG. 3 shows that the control module 13 is located outside the cabinet 2, the actual configuration is not limited thereto. For example, when the size of the control module 13 and the buffer module 12 is small, all the components of the heat exchange system 1 except the second circulation pipe 1010 and the cooling device 101 of the heat exchange module 10 may be located in the cabinet 2. Therefore, the occupied volume of the entire heat exchange system 1 is reduced. However, when the size of the control module 13 and the buffer module 12 is large, all the components of the heat exchange system 1 except a part of the first circulation pipe 100 of the heat exchange module 10 may be located outside the cabinet 2. Therefore, the present embodiment is not limited to the specific positions of the physical components, but merely describes the relative relationship and functions of the various components.

In addition, the heat exchange system 1 of the present disclosure is not limited to be matched with the cooling device 101 (ie, the chilling machine 1011) of the building. In the following, the present disclosure will further provide different connection methods to illustrate different aspects that the heat exchange system 1 of the present disclosure may implement.

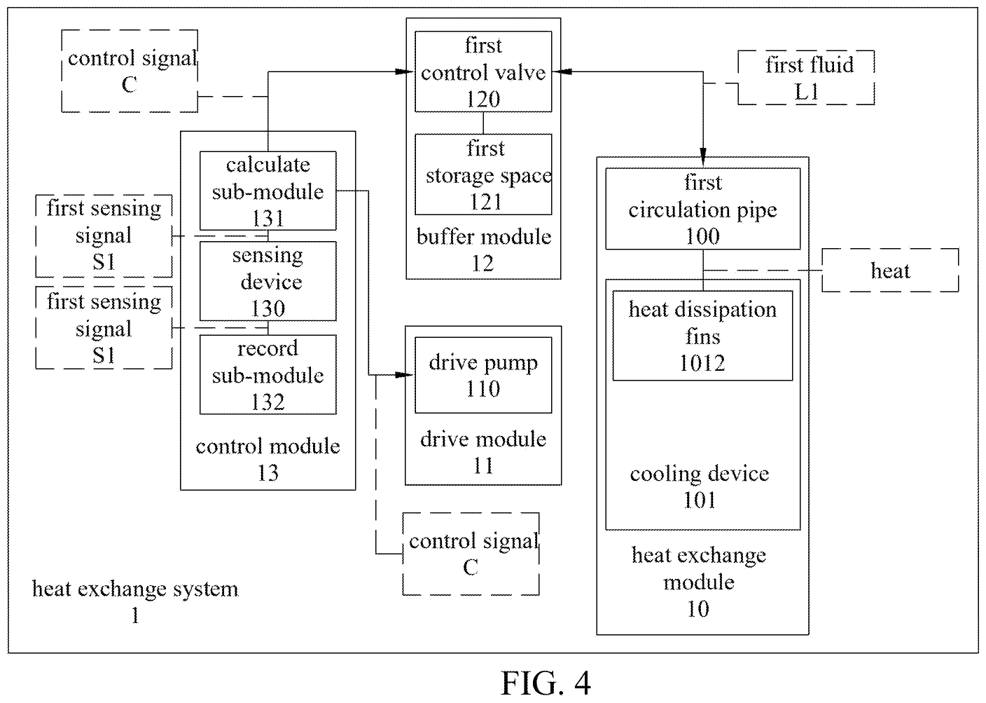

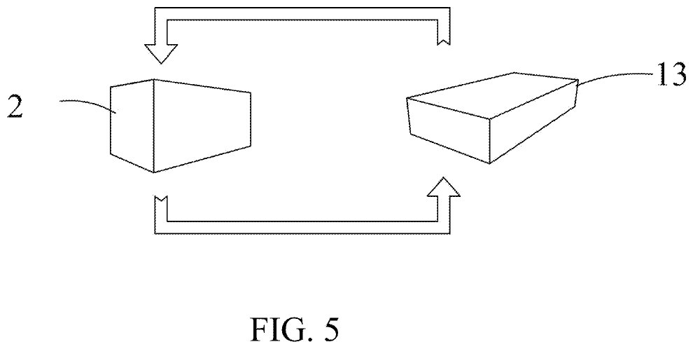

FIG. 4 and FIG. 5 respectively are a block diagram and a schematic diagram of the heat exchange system of the second embodiment of the present disclosure. In the present embodiment, the reference numerals in FIG. 4 and the same reference numerals in FIG. 1 to FIG. 3 have similar or the same function, or are composed of similar or the same material. The detailed description thereof may be referred to the above, which are omitted hereinafter. In the present embodiment, the cooling device 101 includes a plurality of heat dissipation fins 1012, and the first circulation pipe 100 is heat-exchanged with the plurality of heat dissipation fins 1012. In other words, the cooling device 101 of the present embodiment is not a chilling machine or a cooling water tower of the building, and the first circulation pipe 100 is not heat-exchanged with the chilling machine 1011 through the second circulation pipe 1010 either. Further, the first circulation pipe 100 of the present embodiment is heat-exchanged with the air through air cooling (eg, directly through the heat dissipation fins 1012). In this case, the heat exchange system 1 may effectively discharge the heat of the cabinet 2 directly into the environment. It should be noted that when the pipeline of the first circulation pipe 100 is long enough, the heat dissipation fins 1012 may be located in an environment different from the environment where the cabinet 2 is located.

As mentioned above, the heat exchange system 1 of the present embodiment adopts the connection method shown in FIG. 5, which monitors the entire heat exchange process by the control module 13, thereby effectively and stably enabling the cabinet 2 to be in the preset working environment. In addition, only the first circulation pipe 100 and the heat dissipation fins 1012 are used for heat transfer in the present embodiment. Without using the second circulation pipe 1010 and the chilling machine 1011, the present embodiment effectively reduces the occupied volume of the entire heat exchange system 1.

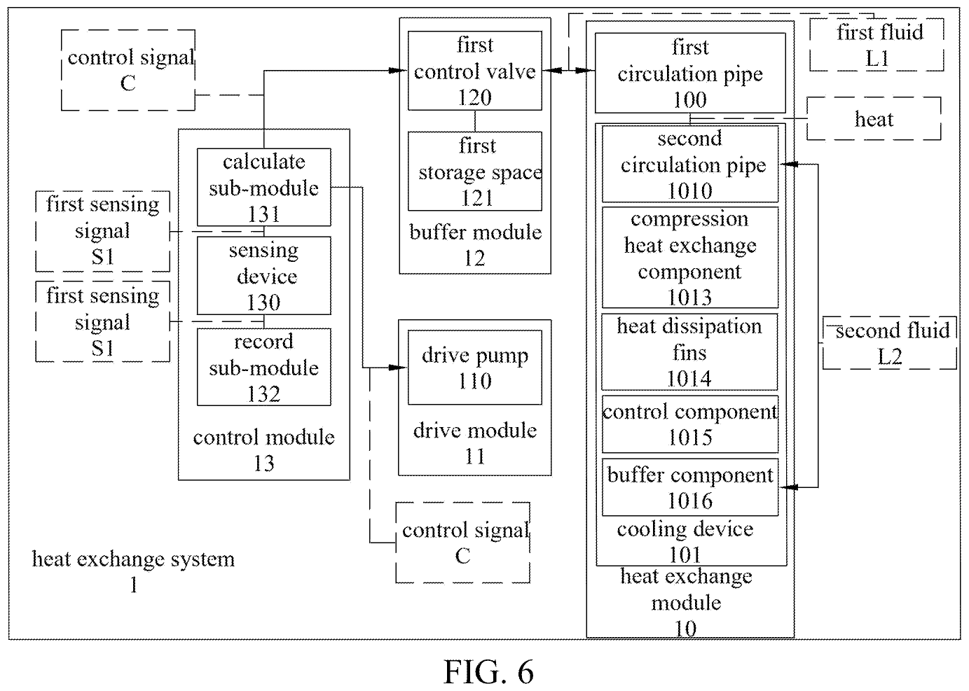

FIG. 6 is a block diagram of the heat exchange system of the third embodiment of the present disclosure. In the present embodiment, the reference numerals in FIG. 6 and the same reference numerals in FIG. 1 to FIG. 3 have similar or the same function, or are composed of similar or the same material. The detailed description thereof may be referred to the above, which are omitted hereinafter. In the present embodiment, the cooling device 101 includes a second circulation pipe 1010, a compression heat exchange component 1013, a plurality of heat dissipation fins 1014, and a control component 1015. The second circulation pipe 1010 is heat-exchanged with but not in fluid communication with the first circulation pipe 100. The compression heat exchange component 1013 is disposed in the second circulation pipe 1010 and compresses the second fluid L2 in the second circulation pipe 1010. A plurality of heat dissipation fins 1014 is heat-exchanged with the second circulation pipe 1010. The control component 1015 is electrically connected to the compression heat exchange component 1013. The control component 1015 includes a sensor, and the control component 1015 controls the compression heat exchange component 1013 according to a second sensing signal sent by the sensor.

In the present embodiment, the cooling device 101 adopts a cooling mode similar to a refrigerating system (ie, a Carnot cooler). Specifically, the cooling device 101 effectively transfers heat from a low temperature to a high temperature through processes such as isothermal expansion, adiabatic expansion, isothermal compression, and adiabatic compression. In this way, the heat exchange system 1 of the present embodiment may be similar to an air conditioning system which may quickly remove the heat of the cabinet 2 and may be not limited to the environment temperature. It should be noted that the elements mentioned above are only examples, and the present disclosure is not limited thereto. Any desired or suitable elements may be disposed by a person having ordinary skills in the ar according to the requirements.

In the present embodiment, the heat exchange module 10, the drive module 11, the buffer module 12, and the control module 13 of the entire heat exchange system 1 may be a complete heat dissipation device, rather than a plurality of components provided respectively. For example, the heat exchange module 10, the drive module 11, the buffer module 12, and the control module 13 of the entire heat exchange system 1 may be located together in the cabinet 2 or on the cabinet 2. In other words, the cabinet 2 may directly dissipate heat through the heat exchange system 1 installed in/on the cabinet 2 without being additionally connected to the cooling water tower of the building or other cooling devices. In this way, the locations of the cabinet 2 may be more diverse. It should be noted that the setting methods mentioned above are only examples, and the present disclosure is not limited thereto. In some embodiments, one or more of the heat exchange module 10, the drive module 11, the buffer module 12, and the control module 13 may be disposed outside the cabinet 2.

In some embodiments, the sensor may include one or more than one of a voltage sensing element, a current sensing element, a fluid temperature sensing element, a fluid pressure sensing element, a fluid flow element, and/or various types of sensing elements well known by a person having ordinary skills in the art, which may effectively monitor the state of the heat exchange module 10. Specifically, the fluid temperature sensing element, the fluid pressure sensing element, the fluid flow element, and other suitable sensing elements generate a second sensing signal according to the measured state of the second fluid L2, and the second sensing signal may include a voltage information, a current information, a fluid pressure information, a fluid temperature information, and a fluid flow information, but the present disclosure is not limited thereto.

In some embodiments, the cooling device 101 further includes a buffer component 1016, and the buffer component 1016 is in fluid communication with the second circulation pipe 1010. The buffer component 1016 includes a second control valve and a second storage space, and the second control valve is located between the second circulation pipe 1010 and the storage space. The control component 1015 controls the second control valve to open or close according to the second sensing signal sent by the sensor. Similar to the function of the buffer module 12, the buffer component 1016 of the present embodiment is also disposed to maintain the flow rate and volume of the second fluid L2 in a better working environment. The detailed description thereof may refer to the hereinbefore, which is omitted herein.

In some embodiments, compression heat exchange component 1013 is provided in plurality, at least one of the plurality of compression heat exchange components 1013 is in a running state, and at least one of the plurality of compression heat exchange components 1013 is in a closed state. Similar to the drive pump 110 mentioned above, through the design of alternate activation, the compression heat exchange component 1013 may not affect the operation of the heat exchange system 1 during maintenance/maintenance. It should be noted that the number mentioned above is only an example. The number of compression heat exchange components 1013 in other embodiments may also be three, four, or more than four, and at least one of the compression heat exchange components 1013 is in a closed state.

In summary, the heat exchange system may monitor the first fluid in the first circulation pipe in real time by the sensing device of the control module, and the heat exchange system may determine whether the temperature and pressure of the first fluid meet the preset state according to the first sensing signal sent by the sensing device. When the pressure and temperature of the first fluid change, the control module may adjust the state of the first fluid through the driving module and even store excess first fluid through the storage module to maintain a stable thermal cycle. Therefore, through the above configuration, a heat exchange system that may effectively dissipate heat and may operate continuously and stably is realized by the present disclosure.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A heat exchange system, comprising:
a heat exchange module comprising a first circulation pipe, wherein a part of the first circulation pipe is penetrated into a cabinet to take away heat of the cabinet;
a drive module connected to the heat exchange module and configured to drive a first fluid in the first circulation pipe to flow along the first circulation pipe;
a buffer module in fluid communication with the first circulation pipe, wherein the buffer module comprises a first control valve and a first storage space, the first control valve is located between the first circulation pipe and the first storage space; and
a electrically connected to the drive module and the buffer module, wherein the control module comprises a sensing device, the control module controls the first control valve to open or close according to a first sensing signal sent by the sensing device and controls the drive module according to the first sensing signal sent by the sensing device.

2. The heat exchange system of claim 1, wherein the control module comprises:
a calculate sub-module receiving the first sensing signal from the sensing device, generating a control signal according to the first sensing signal, and sending the control signal to the buffer module and/or the drive module; and
a record sub-module receiving the first sensing signal from the sensing device and storing a voltage information, a current information, a fluid pressure information, a fluid temperature information, and a fluid flow information of the first sensing signal.

3. The heat exchange system of claim 1, wherein the heat exchange module further comprises a cooling device, and the first circulation pipe is heat-exchanged with the cooling device.

4. The heat exchange system of claim 3, wherein the cooling device comprises a second circulation pipe and a chilling machine, a part of the second circulation pipe is penetrated into the chilling machine to transfer the heat to the chilling machine, and the first circulation pipe is heat-exchanged with but not in fluid communication with the second circulation pipe.

5. The heat exchange system of claim 3, wherein the cooling device comprises a plurality of cooling fins, and the first circulation pipe is heat-exchanged with the plurality of cooling fins.

6. The heat exchange system of claim 3, wherein the cooling device comprises:
a second circulation pipe heat-exchanged with but not in fluid communication with the first circulation pipe;
a compression heat exchange component disposed in the second circulation pipe and compressing a second fluid in the second circulation pipe;
a plurality of heat dissipation fins heat-exchanged with the second circulation pipe; and
a control component electrically connected to the compression heat exchange component and comprising a sensor, wherein the control component controls the compression heat exchange component according to a second sensing signal sent by the sensor.

7. The heat exchange system of claim 6, wherein the cooling device further comprises a buffer component, the buffer component is in fluid communication with the second circulation pipe, the buffer component comprises a second control valve and a second storage space, the second control valve is located between the second circulation pipe and the second storage space, and the control component controls the second control valve to open or close according to the second sensing signal sent by the sensor.

8. The heat exchange system of claim 7, wherein the compression heat exchange component is provided in plurality, at least one of the plurality of the compression heat exchange components is in a running state, and at least one of the plurality of the compression heat exchange components is in a closed state.

9. The heat exchange system of claim 1, wherein the drive module comprises a drive pump, the drive pump is disposed in the first circulation pipe and drives the first fluid in the first circulation pipe.

10. The heat exchange system of claim 9, wherein the drive pump is provided in plurality, at least one of the plurality of the drive pumps is in a running state, and at least one of the plurality of the drive pumps is in a closed state.
